(19) United States
(12) Patent Application Publication
(10) Pub. No.: US 2018/0295306 A1
(43) Pub. Date: Oct. 11, 2018

(54) IMAGE SENSORS WITH DIAGONAL READOUT

(71) Applicant: SEMICONDUCTOR COMPONENTS INDUSTRIES, LLC, Phoenix, AZ (US)

(72) Inventor: Bart CREMERS, Zonhoven (BE)

(73) Assignee: SEMICONDUCTOR COMPONENTS INDUSTRIES, LLC, Phoenix, AZ (US)

(21) Appl. No.: 15/480,521

(22) Filed: Apr. 6, 2017

(51) Int. Cl. H04N 5/378; H01L 27/146

(52) U.S. Cl. CPC H04N 5/378; H01L 27/14612; H01L 27/14643

(57) ABSTRACT

Image sensors may include an array of image sensor pixels. A subset of the array, sometimes referred to as a region of interest (“ROI”), can be read out using vertical readout lines and diagonal readout lines. The diagonal readout lines enable multiple adjacent or nonadjacent rows in the ROI to be simultaneously read out. Configured and operated in this way, frame rate gains can be achieved by reducing the ROI size in both the Y direction and the X direction.

### BACKGROUND

This relates generally to imaging devices, and more particularly, to imaging devices with image sensor pixels.

Image sensors are commonly used in electronic devices such as cellular telephones, cameras, and computers to capture images. In a typical arrangement, an electronic device is provided with an array of image pixels arranged in pixel rows and pixel columns.

Conventionally, each pixel column is connected to a corresponding analog-to-digital converter via a vertical column output line (i.e., all image pixels arranged along a column is connected to a shared vertical pixel output line). Instead of utilizing the entire array of image pixels, only a subset of the array (sometimes referred to as a region of interest or “ROI”) might be used to achieve faster readout at the cost of reduced resolution. However, the frame rate only scales when reducing the ROI size in the vertical Y-direction (i.e., when the ROI includes fewer total rows to be read out). In other words, the frame rate does not scale when reducing the ROI size in the horizontal X-direction (i.e., no speed increase is achieved even when the ROI includes fewer columns to be read out).

It is within this context that the embodiments herein arise.

### BRIEF DESCRIPTION OF THE DRAWINGS

FIG. 1 is a schematic diagram of an illustrative electronic device with an image sensor having diagonal readout circuitry in accordance with an embodiment.

FIG. 2 is a diagram of an illustrative image pixel array that can be coupled to peripheral control circuitry in accordance with an embodiment.

FIG. 3 is a diagram showing how a region of interest (ROI) that covers the entire image pixel array can be read out in accordance with an embodiment.

FIGS. 4-6 are diagrams showing how an ROI that is smaller than the entire image pixel array can be read out in accordance with at least some embodiments.

FIG. 7 is a circuit diagram of an illustrative image sensor pixel that can support the various readout schemes shown in FIGS. 3-6 in accordance with an embodiment.

FIG. 8 is a table showing the state of pixel control signals for different types of image sensor pixels in accordance with an embodiment.

### DETAILED DESCRIPTION

The present embodiments relate to ways for image sensors with column analog-to-digital converters (ADCs) to increase frame rate when reducing not only the vertical region of interest (ROI) size but also when reducing the horizontal ROI size.

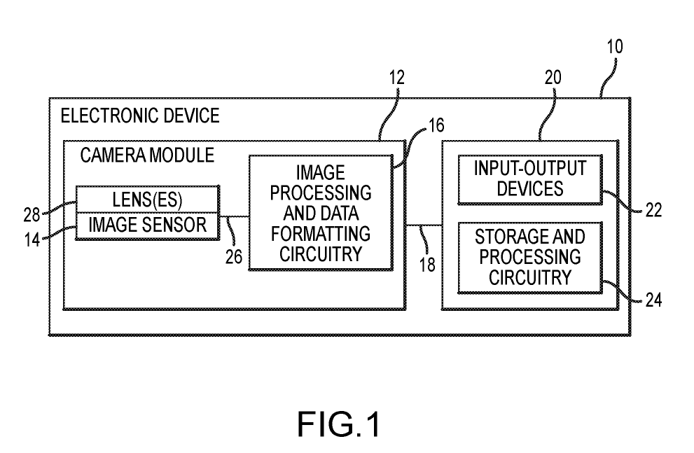

An electronic device with a camera module is shown in FIG. 1. Electronic device 10 (sometimes referred to as an imaging system) may be a digital camera, a computer, a cellular telephone, a medical device, or other electronic device. Camera module 12 (sometimes referred to as an imaging device) may include one or more image sensors 14 and one or more lenses 28. During operation, lenses 28 (sometimes referred to as optics 28) focus light onto image sensor 14.

Image sensor 14 may include photosensitive elements (e.g., pixels) that convert the light into digital data. Image sensors may have any number of pixels (e.g., hundreds, thousands, millions, or more of imaging pixels). A typical image sensor may, for example, have millions of pixels (e.g., megapixels). As examples, image sensor 14 may include bias circuitry (e.g., source follower load circuits), sample and hold circuitry, correlated double sampling (CDS) circuitry, amplifier circuitry, analog-to-digital (ADC) converter circuitry, data output circuitry, memory (e.g., buffer circuitry), address circuitry, etc.

Still and video image data from image sensor 14 may be provided to image processing and data formatting circuitry 16. Image processing and data formatting circuitry 16 may be used to perform image processing functions such as automatic focusing functions, depth sensing, data formatting, adjusting white balance and exposure, implementing video image stabilization, face detection, etc. For example, during automatic focusing operations, image processing and data formatting circuitry 16 may process data gathered by three-dimensional imaging pixels in image sensor 14 to determine the magnitude and direction of lens movement (e.g., movement of lens 28) needed to bring an object of interest into focus.

Image processing and data formatting circuitry 16 may also be used to compress raw camera image files if desired (e.g., to Joint Photographic Experts Group or JPEG format). In a typical arrangement, which is sometimes referred to as a system on chip (SoC) arrangement, camera sensor 14 and image processing and data formatting circuitry 16 are implemented on a common integrated circuit. The use of a single integrated circuit to implement camera sensor 14 and image processing and data formatting circuitry 16 can help to reduce costs. This is, however, merely illustrative. If desired, camera sensor 14 and image processing and data formatting circuitry 16 may be implemented using separate integrated circuits. For example, camera sensor 14 and image processing and data formatting circuitry 16 may be formed using separate integrated circuits that have been stacked.

Camera module 12 may convey acquired image data to host subsystems 20 over path 18 (e.g., image processing and data formatting circuitry 16 may convey image data to subsystems 20). Electronic device 10 (sometimes referred to as a system or imaging system) typically provides a user with numerous high-level functions. In a computer or advanced cellular telephone, for example, a user may be provided with the ability to run user applications. To implement these functions, host subsystem 20 of electronic device 10 may include storage and processing circuitry 24 and input-output devices 22 such as keypads, input-output ports, joysticks, and displays. Input-output devices 22 may also include light sources such as light-emitting diodes that may be used in combination with image sensor(s) 14 to obtain time-of-flight depth sensing information. Input-output devices 22 may include, for example, a light source that emits visible or infrared light.

Storage and processing circuitry 24 may include volatile and nonvolatile memory (e.g., random-access memory, flash memory, hard drives, solid state drives, etc.). Storage and processing circuitry 24 may also include microprocessors, microcontrollers, digital signal processors, application specific integrated circuits, or other processing circuits.

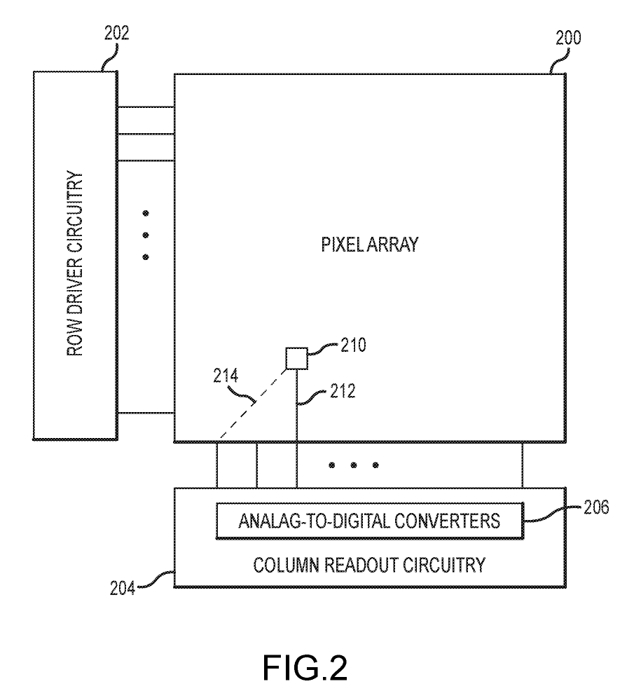

FIG. 2 is a diagram of an illustrative image pixel array 200 that can be coupled to peripheral control circuitry in accordance with an embodiment. As shown in FIG. 2, pixel array 200 may be coupled to row driver circuitry 202 and to column readout circuitry 204. Row driver circuitry 202 may include pointers for selectively accessing one or more rows of image pixels in array 200. Column readout circuitry 204 may include analog-to-digital converters (ADCs) 206 for converting analog signals received from the selected image pixels into digital signals for subsequent digital image processing.

Array 200 may include an array of individual image sensor pixels such as pixel 210. Pixel 210 may be coupled to column readout circuitry 206 via a vertical readout line 212 and also one or more diagonal readout lines 214. The vertical readout line is sometimes referred to as a vertical column readout line since all pixels along a given column are coupled to a common vertical readout line 212. As shown in FIG. 2, vertical readout line 212 and diagonal column line 214 are neither parallel nor perpendicular to each other. In general, lines 212 and 214 may intersect one another at 45 degrees, 30 degrees, 60 degrees, or other suitable angle between 0 and 180 degrees. In some embodiments, the diagonal lines 214 may also be routed in a stair-case wiring configuration (i.e., diagonal lines 214 may include alternating horizontal and vertical segments that route across the diagonal length of the pixel array). Pixel 210 may also receive signals from another pixel 210 via diagonal readout line 214. Pixel 210 may be dynamically coupled to vertical line 212 and/or diagonal line 214 depending on the current readout configuration of array 200.

For example, pixel 210 may only be coupled to vertical line 212 but not diagonal line 214 during a first mode of operation. During a second mode of operation that is different than the first mode, pixel 210 may only be coupled to diagonal line 214 but not vertical line 212. During a third mode of operation that is different than the first and second modes, pixel 210 may be coupled to both lines 212 and 214. During a fourth mode of operation, pixel 210 may be idle and may be decoupled from both lines 212 and 214. These modes are merely exemplary, and other suitable modes for operating pixel 210 coupled to vertical and diagonal readout paths may optionally be employed.

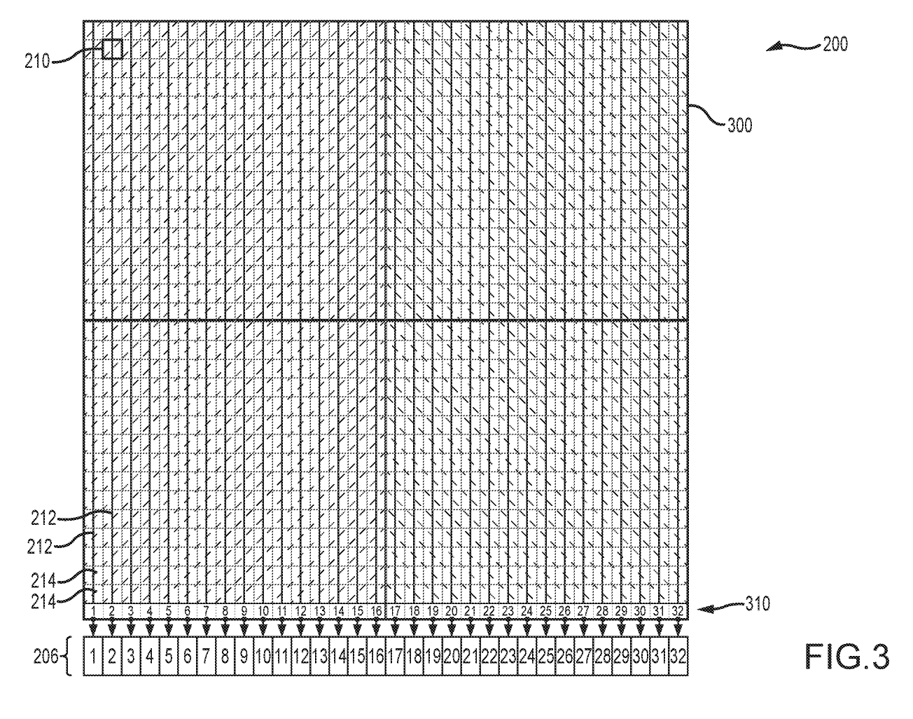

FIG. 3 is a diagram showing how a region of interest (ROI) that covers the entire image pixel array can be read out in accordance with an embodiment. As shown in FIG. 3, ROI 300 (delineated by bolded lines and divided into four quartiles) covers the entire pixel array 200. When ROI 300 covers the entire array 200, every pixel 210 in array 200 will be read out. Pixels 210 in each column are connected to a corresponding vertical readout line 212. Pixels 210 in array 200 are also interconnected using diagonal readout lines 214 (see dotted lines).

When reading out row 310, each pixel 210 along row 310 may output signals that are routed to ADC circuitry 206 via respective vertical readout lines 212. For example, a first (labeled “1”) pixel in row 310 may output an image signal that is conveyed to a first ADC (labeled “1”); a second (labeled “2”) pixel in row 310 may output an image signal that is conveyed to a second ADC (labeled “2”); a third (labeled “3”) pixel in row 310 may output an image signal that is conveyed to a third ADC (labeled “3”); . . . ; and a 32nd (labeled “32”) pixel in row 310 may output an image signal that is conveyed to a last ADC (labeled “32”). Each row may be successively read out in this way.

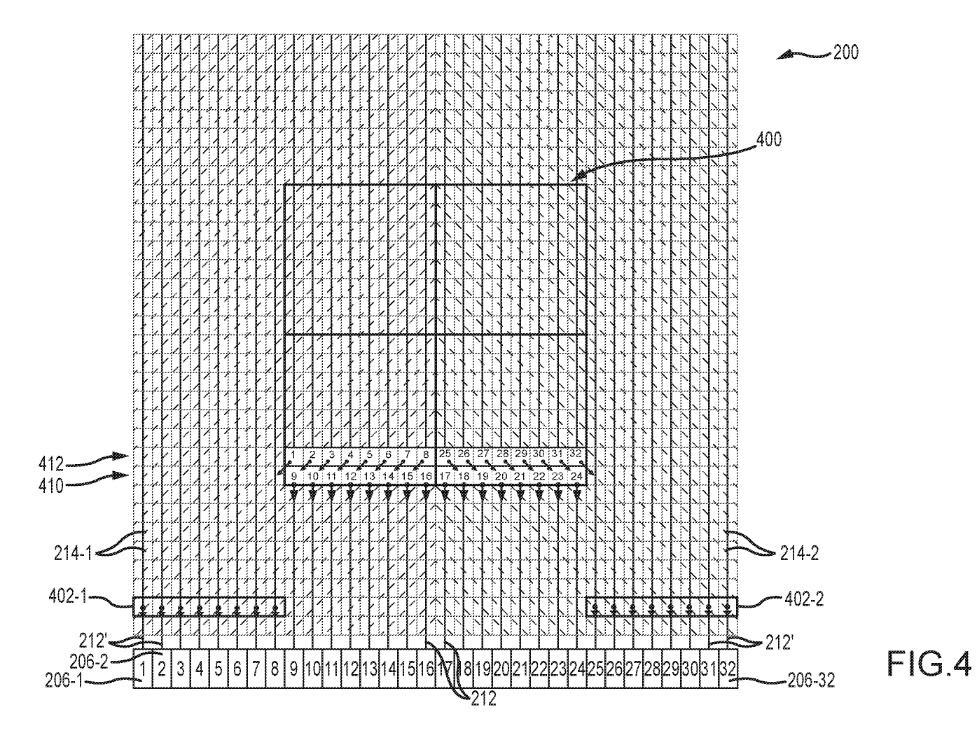

FIGS. 4-6 are diagrams showing how an ROI that is smaller than the entire image pixel array can be read out in accordance with at least some embodiments. FIG. 4 shows an example where adjacent rows within a reduced region of interest such as ROI 400 can be simultaneously read out using both vertical and diagonal readout lines. The pixels along row 410 that are also within ROI 400 (e.g., pixels with indices 9-24) may output signals that are conveyed to corresponding ADCs (also indexed 9-24) via vertical readout lines 212.

The image pixels along row 412 that are also within ROI 400 (e.g., pixels with indices 1-8 and 25-32) may output signals that are conveyed to horizontally displaced pixel groups via diagonal readout lines 214. For example, signals from pixels 1-8 may be routed to pixels within group 402-1 via a first set of diagonal lines 214-1. Similarly, signals from pixels 25-32 may be routed to pixels within group 402-2 via a second set of diagonal lines 214-2. These pixel groups 402-1 and 402-2 outside ROI 400 will then transfer the data from diagonal lines 214 to the corresponding ADC via vertical lines 212′.

For instance, a first pixel in group 402-1 may receive signals from pixel 1 within ROI 400 (e.g., signals routed through a first diagonal line 214-1) and may then transfer the signals to ADC 206-1 via a first vertical readout line 212′. Similarly, a second pixel in group 402-1 may receive signals from pixel 2 within ROI 400 (e.g., signals routed through a second diagonal line 214-1) and may then transfer the signals to ADC 206-2 via a second vertical readout line 212′. As yet another example, a last pixel in group 402-2 may receive signals from pixel 32 within ROI 400 (e.g., signals routed through one of diagonal lines 214-2) and may then transfer the signals to ADC 206-32 via a last vertical readout line 212′ in array 200.

Configured in this way, all the ADCs are utilized even when implementing a reduced ROI. Since ROI 400 only occupies half the number of columns and since two rows can be simultaneously read out, a 4× increase in frame rate can be achieved relative to that of FIG. 3. In other words, the gain in frame rate not only scales with a ROI size reduction in the vertical Y-direction but also with a ROI size reduction in the horizontal X-direction.

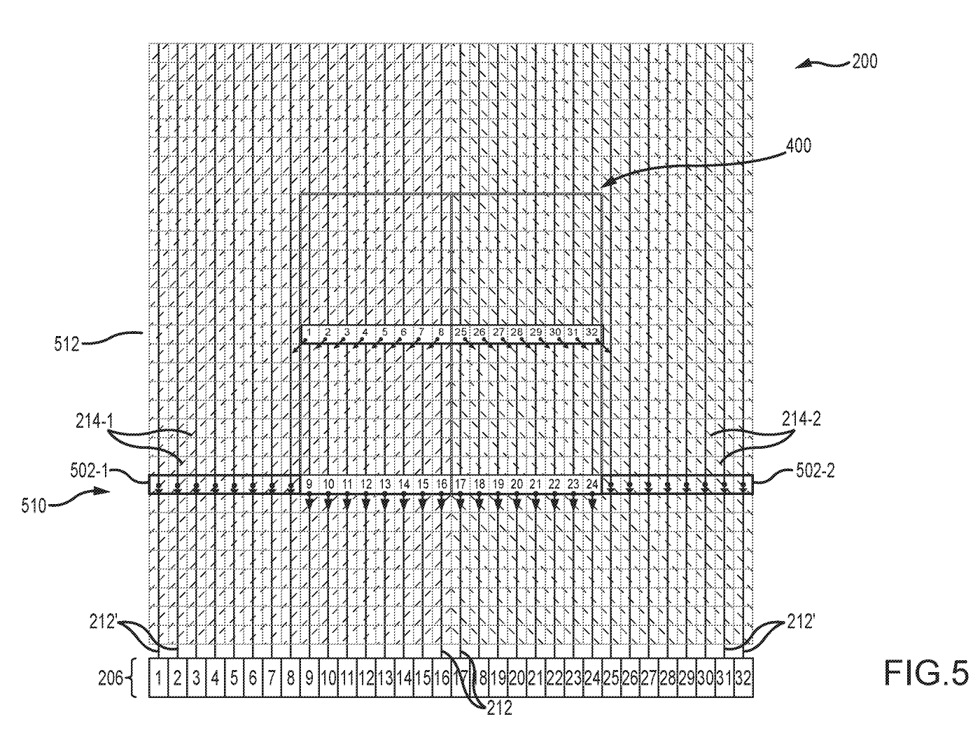

FIG. 5 shows an example where nonadjacent rows within ROI 400 can be simultaneously read out using both vertical and diagonal readout lines. The pixels along row 510 that are also within ROI 400 (e.g., pixels with indices 9-24) may output signals that are conveyed to corresponding ADCs (also indexed 9-24) via vertical readout lines 212.

The image pixels along row 512 that are also within ROI 400 (e.g., pixels with indices 1-8 and 25-32) may output signals that are conveyed to horizontally displaced pixel groups via diagonal readout lines 214. For example, signals from pixels 1-8 may be routed to pixels within group 502-1, which is also in row 510, via a first set of diagonal lines 214-1. Similarly, signals from pixels 25-32 may be routed to pixels within group 502-2, which is also in row 510, via a second set of diagonal lines 214-2. These pixel groups 502-1 and 502-2 outside ROI 400 will then transfer the data from diagonal lines 214 to the corresponding ADC 206 via vertical lines 212′.

The embodiment of FIG. 5 in which simultaneous line/row reads can be vertically separated may be particularly suitable for global shutter sensors. The readout scheme of FIG. 5 may also yield a 4× increase in frame rate relative to that of FIG. 3. In other words, the gain in frame rate not only scales with a ROI size reduction in the vertical Y-direction but also with a ROI size reduction in the horizontal X-direction.

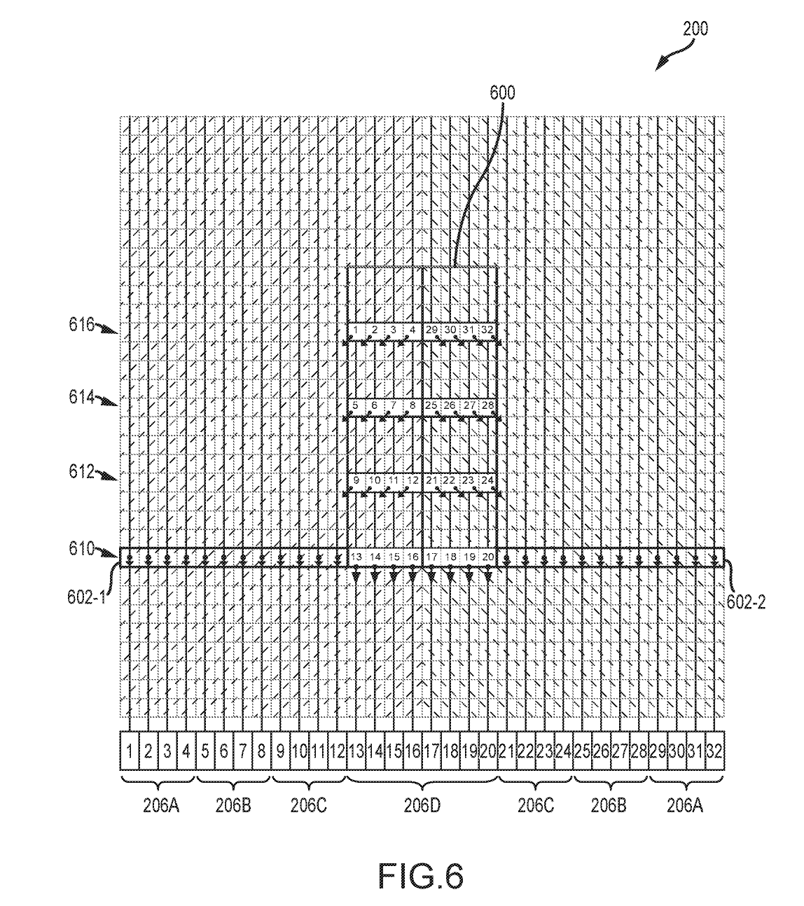

FIG. 6 shows yet another example where more than two nonadjacent rows within a reduced region of interest such as ROI 600 can be simultaneously read out using both vertical and diagonal readout lines. The pixels along row 610 that are also within ROI 600 (e.g., pixels with indices 13-20) may output signals that are conveyed to corresponding ADCs 206D (also indexed 13-20) via the vertical readout lines.

The image pixels along row 612 that are also within ROI 600 (e.g., pixels with indices 9-12 and 21-24) may output signals that are conveyed to a first portion of horizontally displaced pixel groups 602 via the diagonal readout lines. For example, signals from pixels 9-12 may be routed to a first subset of pixels within group 602-1, which is also in row 610, via a first set of diagonal lines. Similarly, signals from pixels 21-24 may be routed to a first subset of pixels within group 602-2, which is also in row 610, via a second set of diagonal lines.

The image pixels along row 614 that are also within ROI 600 (e.g., pixels with indices 5-8 and 25-28) may output signals that are conveyed to a second portion of horizontally displaced pixel groups 602 via the diagonal readout lines. For example, signals from pixels 5-8 may be routed to a second subset of pixels within group 602-1, which is also in row 610, via a third set of diagonal lines. Similarly, signals from pixels 25-28 may be routed to a second subset of pixels within group 602-2, which is also in row 610, via a fourth set of diagonal lines.

The image pixels along row 616 that are also within ROI 600 (e.g., pixels with indices 1-4 and 29-32) may output signals that are conveyed to a third portion of horizontally displaced pixel groups 602 via the diagonal readout lines. For example, signals from pixels 1-4 may be routed to a third subset of pixels within group 602-1, which is also in row 610, via a fifth set of diagonal lines. Similarly, signals from pixels 29-32 may be routed to a third subset of pixels within group 602-2, which is also in row 610, via a sixth set of diagonal lines.

These pixel groups 602-1 and 602-2 outside ROI 600 will then transfer the data from the diagonal lines to the corresponding ADC via the vertical lines. In the example of FIG. 6, the first subset of pixels within groups 602 may be coupled to ADCs 206C. The second subset of pixels within groups 602 may be coupled to ADCs 206B. The third subset of pixels within groups 602 may be coupled to ADCs 206A.

The embodiment of FIG. 6 in which simultaneous line/row reads can be vertically separated into at least four nonadjacent rows may be particularly suitable for global shutter sensors. Since ROI 600 only occupies a quarter of the number of columns in array 200 and since four rows can be simultaneously read out, an additional 2× increase in frame rate can be achieved relative to that of FIG. 5. In other words, frame rate can again be increased by reducing the ROI size in the horizontal X-direction (e.g., by reducing the number of columns in the region of interest).

The examples of FIGS. 3-6 in which the image pixel array includes 32-by-32 image sensor pixels are merely illustrative. In general, the pixel array may include any suitable number of pixels (e.g., thousands or millions of pixels), and the region of interest can be any suitable portion or partial subset of the entire array. If desired, any suitable number of adjacent or nonadjacent rows (e.g., two or more rows, four or more rows, eight or more rows, sixteen or more rows in the array, etc.) can be simultaneously read out using vertical and diagonal readout lines in the way described in connection with FIGS. 2-6.

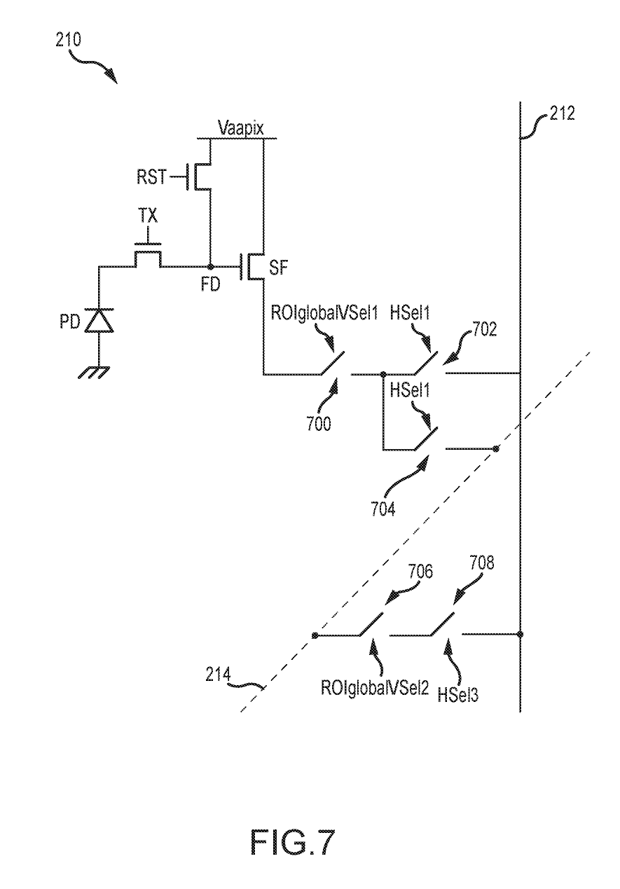

FIG. 7 is a circuit diagram of an illustrative image sensor pixel 210 that can be used to support the various readout schemes shown in FIGS. 3-6 in accordance with an embodiment. As shown in FIG. 7, pixel 210 may include a photodiode PD, a charge transfer gate TX that is coupled to a floating diffusion node FD, a reset transistor coupled between positive power supply line Vaapix and node FD, and a source follower transistor SF having a drain terminal coupled to line Vaapix, a gate coupled to node FD, and a source terminal. This particular pixel implementation is merely illustrative and does not serve to limit the present embodiments. In general, pixel 210 may also include anti-blooming gates, reset gates, storage gates, charge transfer gates, memory nodes, or other control circuitry for operating pixel in rolling shutter mode or global shutter mode in either a front-side illuminated image sensor or a back-side illuminated image sensor.

The source terminal of transistor SF may be coupled to a vertical readout line 212 via transistors 700 and 702 (e.g., transistors 700 and 702 are coupled in series between transistor SF and line 212). Transistor 700 may be controlled by a first ROI global vertical select signal ROIglobalVSel1. Transistor 702 may be controlled by a first horizontal select signal HSel1.

The source terminal of transistor SF may also be coupled to a diagonal readout line 214 via transistors 700 and 704 (e.g., transistors 700 and 704 are coupled in series between transistor SF and line 214). Transistor 704 may be controlled by a second horizontal select signal HSel2.

Diagonal readout line 214 may be coupled to vertical readout line 212 via transistors 706 and 708 (e.g., transistors 706 and 708 are coupled in series between line 214 and line 212). Transistor 706 may be controlled by a second ROI global vertical select signal ROIglobalVSel2. Transistor 708 may be controlled by a third horizontal select signal HSel3.

Signal ROIglobalVSel1 is asserted (i.e., driven high) for pixels inside the ROI but is deasserted (i.e., driven low) for pixels outside the ROI. Signal ROIglobalVSel2 is low for pixels inside the ROI, but high for pixels outside the ROI. The global vertical select signals pulse states only depend on ROI selection (i.e., their states remain fixed during the image capture phase).

Signal HSel1 selects pixels inside the ROI that are read out through the vertical lines (sometimes referred to as the “vertical column set”). Signal HSel2 selects pixels inside the ROI that are read out through the diagonal lines (sometimes referred to as the “diagonal column set”). Signal HSel3 enables the connection of pixels outside the ROI in order to transfer data from the diagonal column set (e.g., the set containing data from pixels inside the ROI) onto the vertical column set that is horizontally displaced from (i.e., outside) the ROI.

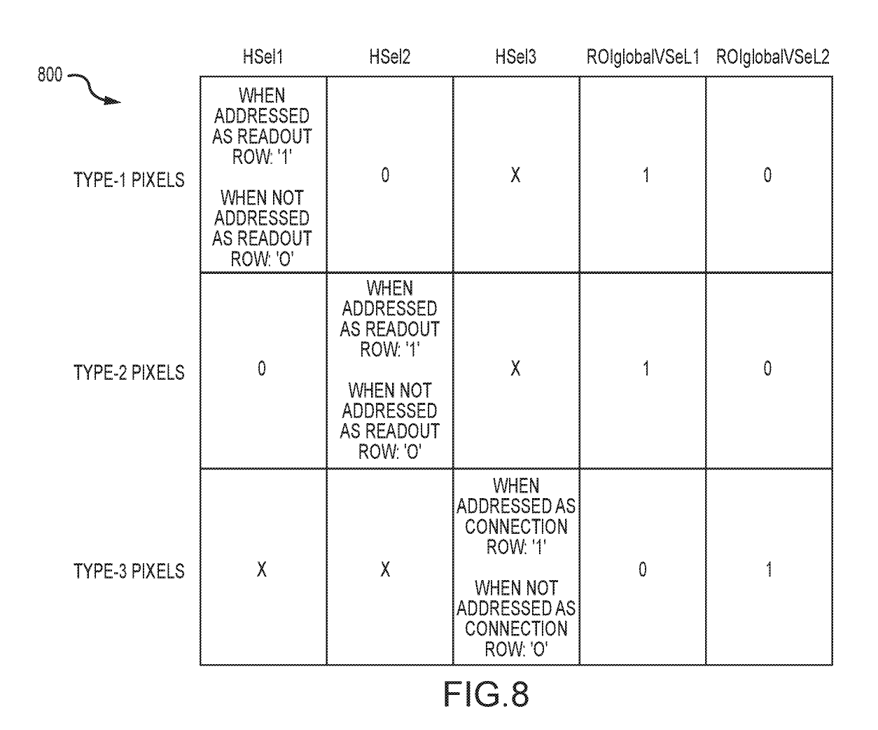

FIG. 8 is a table 800 that summarizes the polarity of the different control signals for different types of image sensor pixels in accordance with an embodiment. The “type-1” pixels are the pixels that are within the ROI and that can be read out using only the vertical readout lines. For type-1 pixels: HSel1 is high when that pixel is addressed as a readout row or is low when that pixel is not addressed as the readout row, HSel2 is low, ROIglobalVSel1 is high, and ROIglobalVSel2 is low. Because ROIglobalVSel2 is low, signal HSel3 is a “don't care” bit (e.g., the state of HSel3 does not matter and can be either low or high, as indicated by symbol “x” in table 800).

The “type-2” pixels are the pixels that are within the ROI but that needs to transfer their signals towards the horizontally displaced pixel groups via the diagonal readout lines. For type-2 pixels: HSel1 is low, HSel2 is high when that pixel is addressed as a readout row or is low when that pixel is not addressed as the readout row, ROIglobalVSel1 is high, and ROIglobalVSel2 is low. Similar with type-1 pixels, HSel3 is a don't care bit since ROIglobalVSel2 is low.

The “type-3” pixels are the pixels that are outside the ROI and that receive signals from the pixels within the ROI via the diagonal readout lines. For type-3 pixels, HSel3 is high when that pixel is addressed as a connection/receiving row or low when that pixel is not addressed as a connection row, ROIglobalVSel1 is low, and ROIglobalVSel2 is high. Because ROIglobalVSel1 is low, both HSel1 and HSel2 are don't care bits.

Table 800 of FIG. 8 is merely illustrative. In general, there may be any number of types of pixels in an image pixel array for supporting vertical readout, diagonal readout, horizontal readout, or other possible readout schemes that can scale with any conceivable reduction in ROI size.

The foregoing embodiments are merely illustrative of the principles of this invention and various modifications can be made by those skilled in the art. The foregoing embodiments may be implemented individually or in any combination.

What is claimed is:

1. An image sensor comprising:
an array of image sensor pixels;
data converters that receive signals from the array of image sensor pixels;
a plurality of vertical readout lines coupling the array of image sensor pixels to the data converters; and
a plurality of diagonal readout lines coupling the array of image sensor pixels to the data converters.

2. The image sensor of claim 1, wherein the data converters comprise analog-to-digital converters.

3. The image sensor of claim 1, wherein the array of image sensor pixels are arranged in rows and columns, and each image sensor pixel in a given one of the columns is coupled to a corresponding common vertical readout line in the plurality of vertical readout lines.

4. The image sensor of claim 3, wherein each image sensor pixel in the given one of the columns is coupled to a different respective diagonal readout line in the plurality of diagonal readout lines.

5. The image sensor of claim 1, wherein a subset of the array comprises a region of interest (ROI), and the array is configured to simultaneously transfer signals from at least two adjacent rows in the ROI to the data converters.

6. The image sensor of claim 1, wherein a subset of the array comprises a region of interest (ROI), and the array is configured to simultaneously transfer signals from at least two nonadjacent rows in the ROI to the data converters.

7. The image sensor of claim 1, wherein a subset of the array comprises a region of interest (ROI), and the array is configured to simultaneously transfer signals from at least four rows in the ROI to the data converters.

8. The image sensor of claim 1, wherein an image sensor pixel in the array is coupled to at least one of the plurality of vertical readout lines and is also coupled to at least one of the plurality of diagonal readout lines.

9. The image sensor of claim 8, wherein the image sensor pixel comprises:
a source follower transistor;
a first select transistor that is coupled between the source follower transistor and the at least one of the plurality of vertical readout lines; and
a second select transistor that is coupled between the first select transistor and the at least one of the plurality of vertical readout lines.

10. The image sensor of claim 9, wherein the image sensor pixel further comprises:
a third select transistor coupled between the first select transistor and the at least one of the plurality of diagonal readout lines.

11. The image sensor of claim 10, wherein the image sensor pixel further comprises:
fourth and fifth select transistors coupled in series between the at least one of the plurality of diagonal readout lines and the at least one of the plurality of vertical readout lines.

12. A method of operating an image sensor, the method comprising:
using an array of pixels in the image sensor to capture an image, wherein the array of pixels are arranged in rows and columns;
simultaneously reading signals out from at least two different rows in the array; and
receiving the signals from the at least two different rows in the array at a plurality of data converters.

13. The method of claim 12, further comprising:
routing the signals from one of the at least two different rows to the plurality of data converters via vertical readout lines; and
routing the signals from another one of the at least two different rows to the plurality of data converters via diagonal readout lines.

14. The method of claim 12, wherein simultaneously reading signals out from at least two different rows in the array comprise simultaneously reading signals out from at least two adjacent rows in the array.

15. The method of claim 12, wherein simultaneously reading signals out from at least two different rows in the array comprise simultaneously reading signals out from at least two nonadjacent rows in the array.

16. The method of claim 12, wherein simultaneously reading signals out from at least two different rows in the array comprise simultaneously reading signals out from at least four different rows in the array.

17. An electronic device comprising:
a camera module with an image sensor, the image sensor comprising:
an array of pixels;
data converters that receive signals from the array of pixels;
diagonal readout lines that route the signals from the array of pixels to the data converters.

18. The electronic device of claim 17, wherein the array of pixels is configured to simultaneously transfer signals from at least two rows in the array to the data converters.

19. The electronic device of claim 17, the image sensor further comprising:
vertical column readout lines that route the signals from the array of pixels to the data converters, wherein the vertical column readout lines and the diagonal readout lines are neither parallel nor perpendicular to each other.

20. The electronic device of claim 19, wherein a pixel in the array of pixels comprises:
a source follower transistor;
a first select transistor coupled between the source follower transistor and at least one of the vertical column readout lines, the first select transistor is controlled by a first global vertical select signal;
a second select transistor coupled between the first select transistor and the at least one of the vertical column readout lines, the second select transistor is controlled by a first horizontal select signal;
a third select transistor coupled between the first select transistor and at least one of the diagonal readout lines, the third select transistor is controlled by a second horizontal select signal;
a fourth select transistor coupled between the at least one of the diagonal readout lines and the at least one of the vertical column readout lines, the fourth select transistor is controlled by a second global vertical select signal; and
a fifth select transistor coupled between the fourth select transistor and the at least one of the vertical column readout lines, the fifth select transistor is controlled by a third horizontal select signal.
